(19) United States
(12) Patent Application Publication
(10) Pub. No.: US 2015/0288143 A1
(43) Pub. Date: Oct. 8, 2015

(54) TUNABLE EXTERNAL CAVITY LASER

(71) Applicant: ELECTRONICS AND TELECOMMUNICATIONS RESEARCH INSTITUTE, Daejeon (KR)

(72) Inventors: Byung Seok CHOI, Daejeon (KR); O Kyun KWON, Daejeon (KR); Ki Soo KIM, Seoul (KR); Jong Sool JEONG, Daejeon (KR); Su Hwan OH, Daejeon (KR); Ki Hong YOON, Daejeon (KR)

(73) Assignee: ELECTRONICS AND TELECOMMUNICATIONS RESEARCH INSTITUTE, Daejeon (KR)

(21) Appl. No.: 14/676,260

(22) Filed: Apr. 1, 2015

(30) Foreign Application Priority Data
Apr. 2, 2014 (KR) 10-2014-0039499

(51) Int. Cl. H01S 5/14; H01S 5/068; H01S 5/125; H01S 5/34

(52) U.S. Cl. CPC H01S 5/141; H01S 5/34; H01S 5/06821; H01S 5/146; H01S 5/125

(57) ABSTRACT

Provided herein is a tunable external cavity laser comprising: a gain medium configured to create an optical signal; an external reflector configured to be coupled to the gain medium, and to comprise a Bragg grating; and a phase control section configured to adjust a phase of an entire laser, but to adjust a wavelength of the laser to a longer wavelength than a peak reflectivity of the external reflector.

### CROSS-REFERENCE TO RELATED APPLICATIONS

The present application claims priority to Korean Patent Application No. 10-2014-0039499, filed on Apr. 2, 2014, the entire disclosure of which is incorporated herein its entirety by reference.

### BACKGROUND

1. Field

The following description relates to a tunable external cavity laser, and more particularly to a tunable external cavity laser with improved chirp characteristics.

2. Description of Related Art

Research is actively being conducted on passive optical networks (PON) which has their basis on wavelength division multiplexing (WDM) (hereinafter referred to as ‘WDM-PON’). WDM-PON is capable of providing voice, data and broadcast integrated services.

In WDM-PON, communication is made between a center office (CO) and subscribers using a wavelength set for each subscriber. Furthermore, WDM-PON uses an exclusive wavelength for each subscriber, and thus is highly secured, enables large scale communication services and application of transmission techniques having different link rates and frame formats for each substrate or service.

However, WDM-PON is a technique of multiplexing various wavelengths in a single optical fiber using the WDM technology, and thus it needs different light sources as many as the number of subscribers belonging to one remote node (RN). As such, producing, installing and managing these light sources for each wavelength can be a big economical burden to both the users and operators, that is, a great obstacle to commercializing WDM-PON. In order to resolve this problem, research is actively underway regarding ways to apply tunable light source devices where the wavelength of light source can be selectively tuned.

FIG. 1 illustrates a configuration of a general WDM-PON where a broadband light source is used.

Referring to FIG. 1, WDM-PON 100 consists largely of an optical line terminal (OLT, 110) that is disposed at a CO side, an optical network unit or optical network terminal (ONU/ONT, 130) that is disposed at a subscriber's side, and an RN 120. The OLT 110 and the RN 120 are connected to each other by a single-core feeder optical fiber 117, and the RN 120 and the ONU/ONT 130 are connected to each other by a distribution optical fiber 125.

A downward light is transmitted from a broadband light source (BLS, 112) inside the OLT to a reflective semiconductor optical amplifier (RSOA, 111) for OLT use via a first optical circulator 114 and an arrayed waveguide grating 113 configured to perform WDM multiplexing/demultiplexing functions. And then the downward light is transmitted from the RSOA 111 for OLT use to an AWG 123 of the RN 120 through the feeder optical fiber 117 via the AWG 113, first optical circulator 114 and second optical circulator 115 again, and then the downward light is finally transmitted to an optical transmitter 131 and optical receiver 132 for ONU use through the distribution optical fiber 125 via 1×2 optical coupler (or circulator, 133) inside the ONU/ONT 130.

An upward light is transmitted in the opposite direction to the aforementioned downward light. In other words, the upward light is transmitted from the optical transmitter 131 for ONU use to the optical receiver 116 for OLT use via the 1×2 optical coupler 133, distribution optical fiber 125, AWG 123 of the RN 120, feeder optical fiber 117, second optical circulator 115 and AWG 118.

The WDM-PON 100 that uses broadband light source also uses the light source of the OLT 110 side at the ONU 130 as well, and thus there is no need to secure additional light source at the subscriber's end, thereby having an advantage of providing a colorless system. However, the WDM-PON 100 that uses broadband light source uses additional broadband light source to inject seed light source, and amplifies and modulates this at the RSOA 111, thereby causing limitation of speed. Thus, it is regarded as a method not suitable for use in a 10 Gbps grade system. To compensate this disadvantage, devices wherein a reflective electro-absorption modulator is integrated are emerging as an alternative.

FIG. 2 illustrates a configuration of a general WDM-PON where tunable light source is used.

Referring to FIG. 2, the WDM-PON 200 comprises an OLT 210 disposed at a CO side, an ONU/ONT 230 disposed at a subscriber's side, and an RN 220. The OLT 210 and the RN 220 are connected by a single-core feeder optical fiber 217, and the RN 220 and the ONU/ONT 230 are connected by a distribution optical fiber 225.

A downward light is transmitted from a tunable laser diode (TLD, 211) of the OLT 210 to a photodiode 232 via a WDM filter 213, AWG 214, feeder optical fiber 217, AWG 223, distribution optical fiber 225, and WDM filter 233. An upward light is transmitted to a photodiode (PD, 212) of a base station transmitter 210 in the opposite direction to the aforementioned downward light.

Unlike the WDM-PON 100 of FIG. 1, the WDM-PON 200 of FIG. 2 uses tunable laser diodes 211, 231 each for the OLT 210 and ONU/ONT 230, respectively, in order to configure a system that does not depend on wavelength. The WDM-PON 200 that uses tunable laser diode is limited such that the ONU/ONT 230 each has its light source, respectively, but it has an advantage of realizing high performance in terms of speed since it uses laser. The key to realizing such a system lies on whether or not it is possible to manufacture a reliable and high performance tunable laser diode at low cost.

### SUMMARY

Therefore, the purpose of the present disclosure is to resolve the aforementioned problems, that is to provide a tunable external cavity laser with improved chirp characteristics.

In one general aspect, there is provided a tunable external cavity laser comprising a gain medium configured to create an optical signal; an external reflector configured to be coupled to the gain medium and to comprise a Bragg grating; and a phase control section configured to adjust a phase of the entire laser, but adjusting a wavelength of the laser to a longer wavelength region than a maximum spectral reflectivity of the external reflector.

As aforementioned, according to the present disclosure, there is provided a tunable external cavity laser comprising a phase control section configured to adjust a phase such that oscillation is made in a longer wavelength region than a maximum spectral reflectivity of the external reflector, whereby the tunable external cavity laser has low chirp characteristics, and may transmit signals to as far as tens of kilometers away at a high transmission speed of 10 Gb/s grade or above.

### BRIEF DESCRIPTION OF THE DRAWINGS

FIG. 1 is a configuration of a general WDM-PON using broadband light source.

FIG. 2 is a configuration of a general WDM-PON using tunable laser diode.

FIG. 3 is a graph showing changes in reflectivity vs. wavelength in an external reflector comprising a typical distributed Bragg grating (DBR).

FIGS. 4A and 4B are graphs for explaining the relationship between reflectivity bandwidth and modulation bandwidth according to changes in the length of grating in a tunable external cavity laser according to an exemplary embodiment of the present disclosure.

FIG. 5 illustrates a configuration of a tunable external cavity laser according to an exemplary embodiment of the present disclosure.

FIGS. 6A and 6B are views for explaining positions of a phase control section in an tunable external cavity laser according to an exemplary embodiment of the present disclosure.

FIG. 7 is a graph showing changes in an effective LEF made by phase adjustment.

FIGS. 8A and 8B are graphs showing changes in an LEF and reflectivity vs. an entire laser cavity length.

FIG. 9 is a graph of bit error rates vs. signal transmission in a tunable external cavity laser according to an exemplary embodiment of the present disclosure.

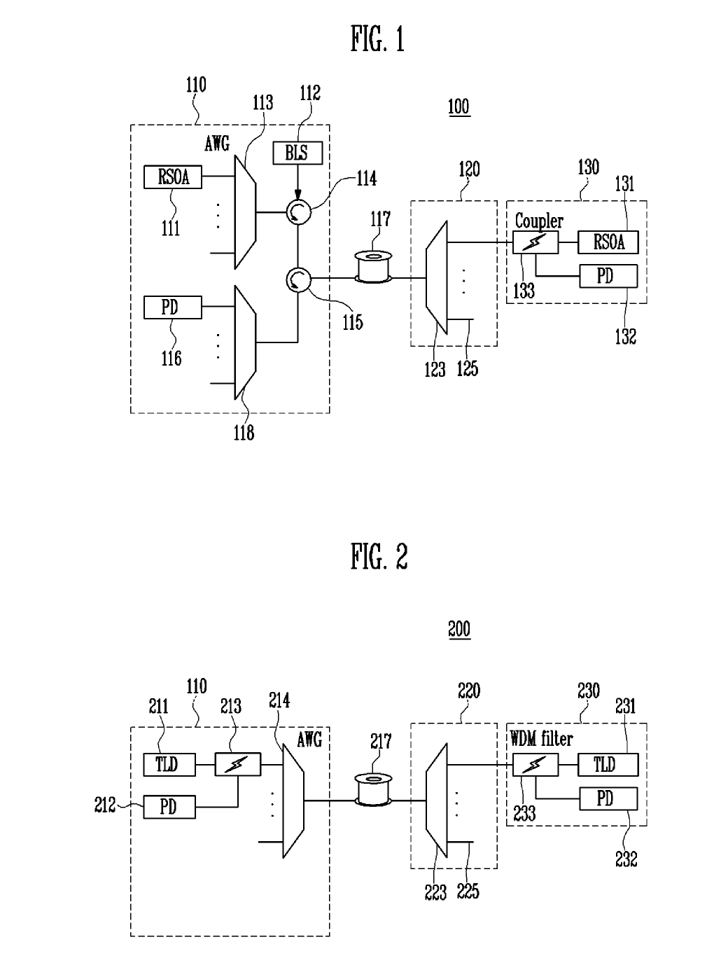

Throughout the drawings and the detailed description, unless otherwise described, the same drawing reference numerals will be understood to refer to the same elements, features, and structures. The relative size and depiction of these elements may be exaggerated for clarity, illustrating, and convenience.

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

Although a few embodiments of the present invention have been shown and described, it would be appreciated by those skilled in the art that changes may be made in this embodiment without departing from the principles and spirit of the invention, the scope of which is defined in the claims and their equivalents.

Generally, the transmission distance of an optical signal is determined by linewidth and power that an optical signal has, and in a 1.55 μm band, the transmission distance of an optical signal is determined mostly by a linewidth. When a laser only oscillates, the linewidth is determined by a phase noise, but when there is a signal modulation process, the linewidth of the optical signal increases more than the bandwidth of the modulated optical signal. Such changes in the linewidth of an optical signal is called chirp. Due to the dispersive characteristics of optical fiber, the longer the transmission distance, the finite linewidth of the optical signal becomes wider, thereby deteriorating transmission characteristics. An increase of linewidth of an optical signal by a change in bias current is called adiabatic chirp, while an increase of linewidth of an optical signal at a region where a wavelength is changed by amplitude modulation is called transient chirp.

Meanwhile, when processing data at a high speed, the effects of transient chirp increases even more. Herein, the proportional constant of the increased linewidth is called linewidth enhancement factor (LEF), whereby chirp characteristics may be defined and changes of linewidth of light source may be predicted. The smaller the LEF, the better, and if LEF has a negative(−) value, the linewidth of an optical signal may become narrower at an initial stage of processing the optical signal.

In general, a laser having a quantum-well layer structure is known to have an LEF of about 3-7, and a laser having a bulk layer structure is known to have a greater value. Ways of reducing such an LEF includes a method of reducing the LEF in a semiconductor quantum-well layer itself(when direct modulating); and a method of modulating an optical signal using an external modulator having a small LEF value such as an Electro-Ab sorption Modulator (EAM) or Mach-Zehnder Modulator (MZM). The method of reducing an LEF in a semiconductor quantum-well layer itself includes a method of using a quantum-well structure to increase a differential gain thereby reducing the LEF, and a method of reducing an LEF using a quantum dot, but these methods are not easy to realize. In addition, in the method of reducing an LEF using EAM or MZM, attempts were made to integrate EAM or MZM into the laser, but this was not easy either due to difficulty in manufacturing an integrated device. Besides the above, various methods such as the method of reducing an LEF using a semiconductor amplifier were proposed, but these are also not advantageous in terms of cost since additional devices are used.

In addition, it is already well known that when operating in a longer wavelength region on a spectral reflectivity of an external reflector in an external cavity laser structure, there is an effect of LEF being reduced. This is called detuned loading effect, which is one of the overall improved characteristics of an external cavity laser. External cavity lasers of related art were mostly used to obtain narrow linewidth while performing continuous wave (CW) operations, but recent external cavity lasers use the detuned loading effect as they are used in high speed modulation. At a modulation speed of not more than 2.5 Gb/s, the bandwidth limitations due to the length of an external cavity is not so great, and thus there is no problem in providing an optical system using a general lens optical system. Furthermore, since signal transmission of tens of kilometers can be realized with only the LEF of a semiconductor medium itself, it was not so necessary to reduce the LEF. However, in cases where the transmission speed has to be at least 10 Gb/s grade or above in a 1550 nm wavelength band, signals can be transmitted to only several kilometers due to the intersymbol interference caused by the dispersion of optical fibers and the chirp of optical signal, and thus reducing the LEF becomes most important.

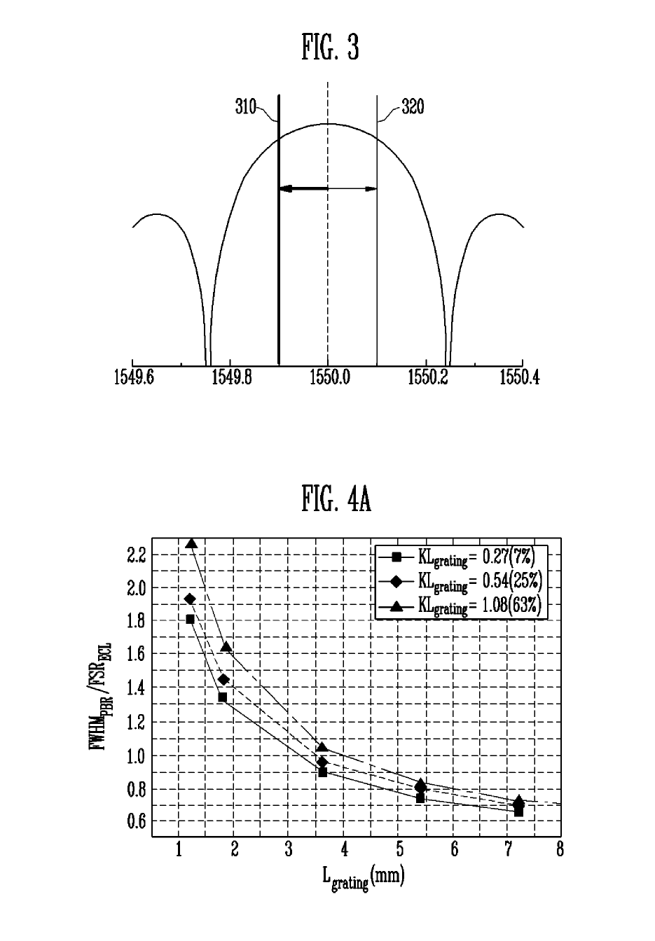

A method of reducing an LEF in a tunable external cavity laser according to an exemplary embodiment of the present disclosure will be explained hereinafter with reference to FIG. 3.

FIG. 3 is a graph showing changes in reflectivity vs. wavelength (spectral reflectivity) in an external reflector comprising a typical distributed Bragg grating (DBR).

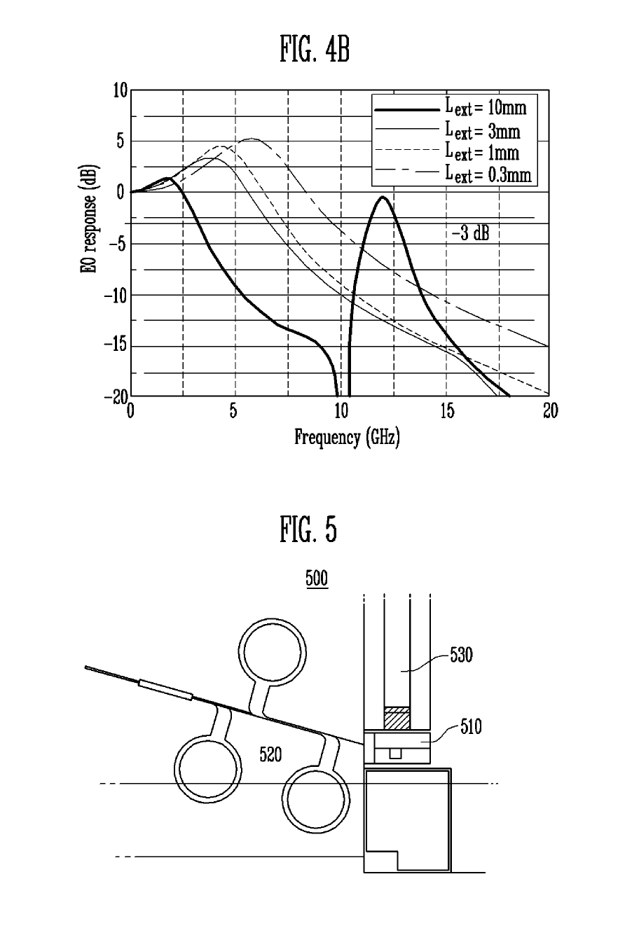

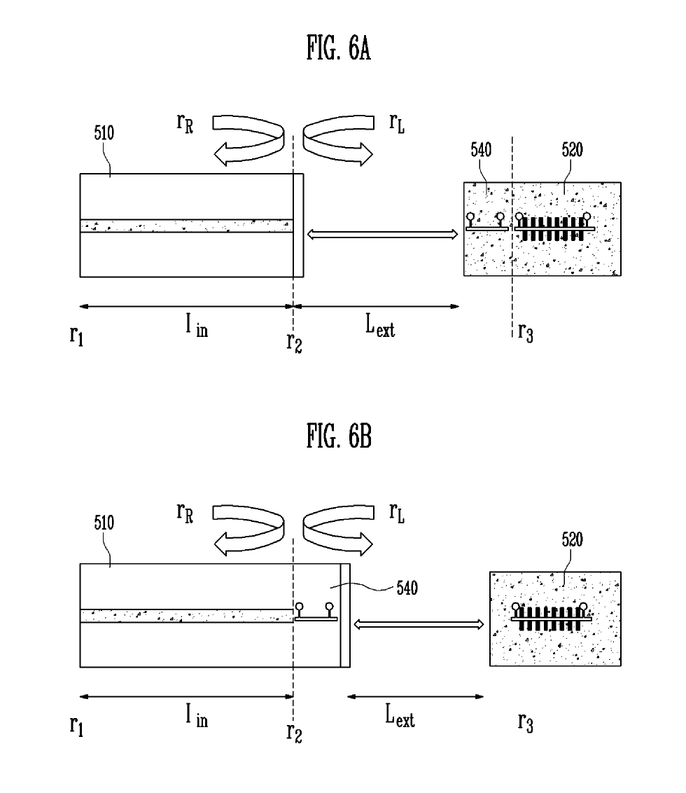

Referring to FIG. 3, depending on the structure of an external cavity laser and operational conditions thereof, when the external cavity laser operates in the longer wavelength region 320 based on the wavelength where the reflectivity of the external reflector has the maximum value, the aforementioned detuned loading effect may be obtained. The detuned loading effect increases as the slope of the spectral reflectivity increases, and thus it is preferable that the external cavity laser operates in a longer wavelength region that is far from the wavelength where the reflectivity of the external reflector has the maximum value. However, since when there are numerous potential modes where lasing may occur, the mode having the maximum gain is lased, there is limitation to the range by which laser mode can move. FIG. 4A is the graph showing this relationship, where the full width at half maximum (FWHM) is the 3 dB spectral bandwidth of DBR, the free spectral range (FSR) denotes the range between modes of the laser, L denotes the length of the grating portion in the DBR and κ is the coupling coefficient of the grating. The smaller the value FWHM/FSR that denotes the ratio of FWHM and FSR, the relatively farther the lasing mode can move on the spectral reflectivity curve of the DBR, and thus a smaller FWHM/FSR value is advantageous to reduce the LEF. As illustrated in FIG. 4A, the longer the grating, the smaller the FWHM/FSR value, and thus would be advantageous in obtaining a small LEF, but due to the elongated grating, the electrical-to-optic (EO) modulation bandwidth is reduced. FIG. 4B is a graph showing this relationship, that is, this graph shows the changes of the EO modulation response as a function of modulation frequency when the distance (Lₑₓₜ) between the two elements illustrated in FIGS. 6A and 6B is varied. In an external cavity laser, when the entire laser cavity length gets longer, the bandwidth is reduced, and it can be seen that for the external cavity laser to operate at or above 10 Gb/s grade, the entire laser cavity length must be not more than 8 mm when converted into free space (when Lₑₓₜ of 3 mm is used). Therefore, since the length of the grating that accounts for a portion of the entire laser cavity is also limited, approximately not more than 8 mm becomes the maximum length of the grating.

Therefore, in a tunable cavity laser according to the present disclosure, it is preferable that the gain medium and the external reflector are butt-coupled in order to minimize the reduction of bandwidth by the length of grating.

A configuration of a tunable cavity laser according to the present disclosure will be explained hereinafter.

FIG. 5 illustrates a configuration of a tunable external cavity laser according to an exemplary embodiment of the present disclosure.

Referring to FIG. 5, a tunable external cavity laser according to exemplary embodiments of the present disclosure comprises a gain medium 510 configured to create and amplify an optical signal, an external reflector 520 configured to be coupled to the gain medium to form a mirror surface, and a high frequency transmission medium 530 configured to apply a high frequency signal to the gain medium 510.

The gain medium 510 creates and amplifies an optical signal by bias current being applied. Herein, when the applied bias current is or above a critical value, a lasing occurs within a laser cavity formed by the gain medium 510 and external reflector 520.

The external reflector 520 is an optical waveguide structure that may be directly coupled to the gain medium 510 to form a laser cavity, and the external reflector 520 may comprise a Bragg grating.

The high frequency transmission medium 530 applies a high frequency signal to the gain medium 510 such that the size of the optical power is adjusted according to the high frequency signal.

As illustrated in FIGS. 6A and 6B, a tunable external cavity laser 500 according to the present disclosure comprises a phase control section 540 to obtain detuned loading effect through lasing in the longer wavelength region. More reduced LEF may be obtained than predicted by the reflectivity, which can be explained by the nonlinear gain phenomenon of the tunable external cavity laser 500.

When a lasing occurs, the gain changes due to the coupling of the modes in the tunable external cavity laser 500, whereby two phenomena may occur. One is the effect of suppressing the gain of the other modes besides the lasing mode, which is called a self-stabilization effect, providing an effect of expanding the stabilization region of the lasing mode. The main mechanism is caused by the spectral hole burning and carrier heating phenomena, by which a symmetric nonlinear gain occurs. The other one enhances the gain in the longer wavelength region, whereby the stability region moves towards the longer wavelength side. The main mechanism is the carrier density pulsation phenomenon, whereby the gain obtained herein is called an asymmetric nonlinear gain. Therefore, once a lasing starts, even if the lasing mode is detuned to the longer wavelength region, the mode-hopping phenomenon to other modes is restrained, and thus the mode continues to lase actively in regions outside the region predicted by the static gain condition. Accordingly, the tunable external cavity laser 500 obtains a greater detuned loading effect, advantageously acting on the transmission distance.

In addition, the phase control section 540 may be coupled to the external reflector 520 as illustrated in FIG. 6A, and coupled to the gain medium 510 as illustrated in FIG. 6B.

The phase control section 540 makes a fine change in the refractive index and adjusts the phase (spectral position of modes in ECL). Methods of using the phase control section 540 may include a method based on temperature adjustment and a method based on applying current or voltage. The temperature adjustment method is based on the thermo-optic effect of the material, and this method can be used regardless of where the phase control section 540 is positioned in the semiconductor gain medium or external reflector of a polymer material having a high thermo-optic coefficient. However, this method is relatively slow compared to the electrical control method (current or voltage). The method based on application of current is a method of using the free-carrier plasma effect, and the method based on application of voltage is a method of using Franz-Keldysh or Quantum-confined Stark effect, but these methods have a disadvantage that while they are applicable when the external reflector 520 is made of a semiconductor medium, they are not applicable when the external reflector 520 is made of a polymer material. In addition, in the method based on application of current or voltage, when the phase control section 540 exists in the gain medium 510, the electrical characteristics of the gain medium 510 may be affected by the phase adjustment of the phase control section 540, and thus attention has to be paid on isolation when integrating the two elements.

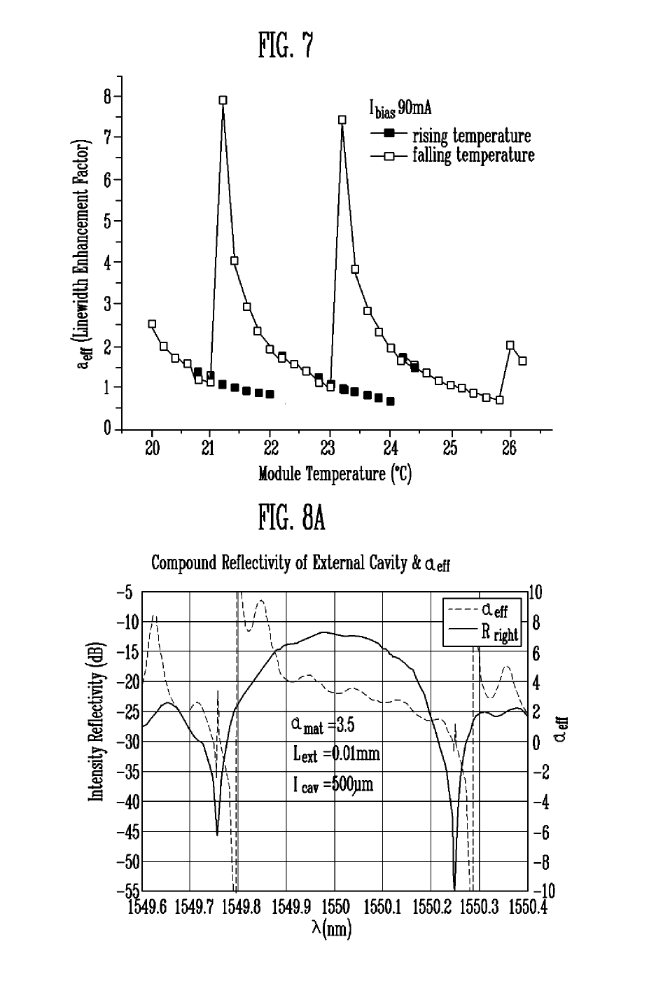

FIG. 7 is a graph showing changes in effective LEF (LEF changed by the detuned loading effect) made by phase adjustment. Herein, a polymer based tunable external reflector was used, and a module including the gain medium and external reflector was placed on a thermo-electric cooler, and a thermistor was attached to a side of the gain medium to monitor the temperature. Phase adjustment was made by the thermo-optic effect where the refractive index changes as temperature changes.

Referring to FIG. 7, the LEF of the semiconductor gain medium itself was 3.5, but after forming an external cavity laser and rising the temperature of the module and moving the lasing mode to the longer wavelength region, the LEF gradually decreased to about 1. While the LEF that can be obtained by the static gain condition is about 1.9, it can be seen that by moving the lasing mode further to the longer wavelength region lased by the aforementioned nonlinear gain phenomenon, a smaller LEF can be obtained. Meanwhile, it can be seen that by adjusting the module temperature in the falling temperature direction, the lasing mode moves to the short wavelength region, resulting in a LEF having a greater value. Herein, it can be seen that two effective LEFs were measured according to the direction in which the temperature is changed on same conditions, meaning that one of the two modes may exist depending on the direction of temperature change. In addition, it can be seen that in order to obtain such a chirp reduction effect, of the two potential lasing modes, the longer wavelength mode must be selected.

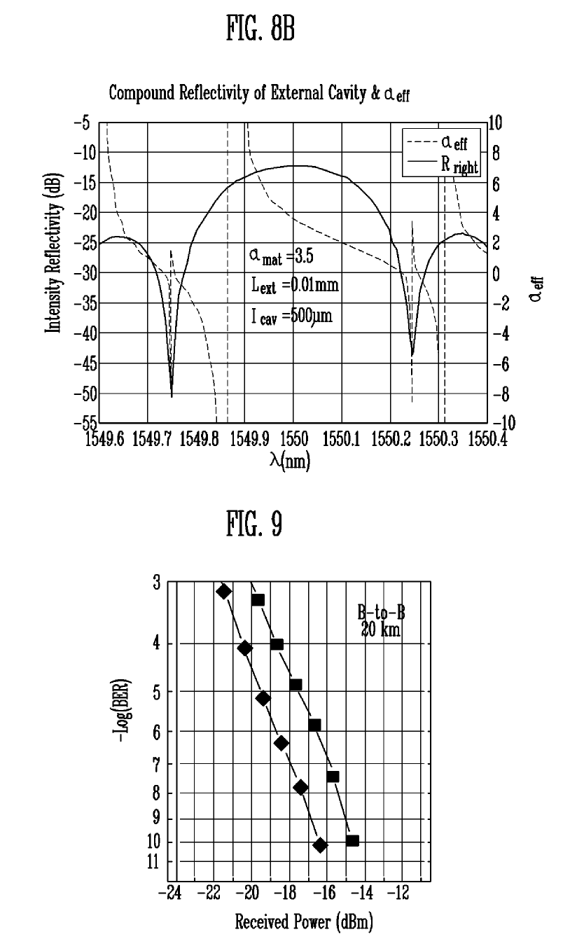

FIGS. 8A and 8B are graphs showing changes in effective LEF for the given spectral reflectivity R_{right}, which is composed of the reflectivity of the external reflector and residual reflectivity on the anti-reflection coated facet. More specifically, FIG. 8A is a graph showing the changes of the effective LEF when the distance between the gain medium and the external reflector Lₑₓₜ is 10 mm, and FIG. 8B is a graph showing the changes of the LEF when the distance between the gain medium and the external reflector is 10 μm (the material LEF αₘₐₜ and the length of the gain medium l_{cav} are 3.5 and 500 μm, respectively).

When an optical coupling is made between the gain medium and the external reflector by the lens, the distance between the gain medium and the external reflector would be about 10 mm, and when an optical coupling is made between the gain medium and the external reflector by a butt-coupling method, the distance between the gain medium and the external reflector would be about 10 μm.

Referring to FIG. 8, it can be seen that the α_{eff} (effective LEF) that is used as a coefficient for excessive chirp that actually affects the transmission performances decreases far more quickly when the distance between the gain medium and the external reflector is 10 μm compared to when the distance between the gain medium and the external reflector is 10 mm.

FIG. 9 is a graph of bit error rates as a function of received power for a tunable external cavity laser according to an exemplary embodiment of the present disclosure. More specifically, FIG. 9 shows the measured results of bit error ratio (BER) under the back-to-back condition and after transmission over 20-km-long single mode fiber for the signals of a tunable external cavity laser modulated at 10 Gb/s according to an exemplary embodiment of the present disclosure.

As illustrated in FIG. 9, it is possible to realize an external cavity laser using a gain medium having an LEF capable of transmitting a signal to several kilometers, and thus the detuned loading effect to transmit the signal to 20 km, wherein the power penalty of the signal shows an excellent value of within 2 dB.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A tunable external cavity laser comprising:
a gain medium configured to create an optical signal;
an external reflector configured to be coupled to the gain medium, and to comprise a Bragg grating; and
a phase control section configured to adjust a phase of an entire laser, and to adjust a wavelength of the laser to a longer wavelength region than a peak reflectivity of the external reflector.

2. The tunable external cavity according to claim 1, wherein the external reflector comprises a tunable reflector.

3. The tunable external cavity according to claim 1, wherein the phase control section is integrated to the gain medium.

4. The tunable external cavity according to claim 1, wherein the phase control section is integrated to the external reflector.

5. The tunable external cavity according to claim 1, wherein the gain medium and the external reflector are coupled to each other by a butt-coupling method.
